(19) United States
(12) Patent Application Publication
(10) Pub. No.: US 2012/0111616 A1
(43) Pub. Date: May 10, 2012

(54) ELECTRONIC-COMPONENT-MOUNTED WIRING SUBSTRATE AND METHOD OF MANUFACTURING THE SAME

(75) Inventors: Masahiro INOUE, Konan-shi (JP); Hajime SAIKI, Konan-shi (JP); Atsuhiko SUGIMOTO, Kagamigahara-shi (JP)

(73) Assignee: NGK SPARK PLUG CO., LTD., Nagoya-shi (JP)

(21) Appl. No.: 13/290,737

(22) Filed: Nov. 7, 2011

(30) Foreign Application Priority Data
Nov. 8, 2010 (JP) 2010-249871

(51) Int. Cl. H05K 1/09; B23K 31/02; B23K 1/00

(52) U.S. Cl. 174/257; 228/180.1

(57) ABSTRACT

An electronic-component-mounted wiring substrate provides enhanced joining reliability when an electronic component is joined to terminal pads of the wiring substrate, has sufficient strength, and can prevent generation of warpage and formation of a short circuit, which would otherwise occur as a result of re-melting of solder. Solder completely covers an entire surface of each of the terminal pads provided on a laminated substrate such that they project therefrom, and also joins to terminals of the electronic component. Therefore, each of the terminal pads and the solder are joined together reliably, and sufficient electrical continuity is secured therebetween. That is, the reliability of a joint between the solder and each terminal pad is extremely high, and the reliability of joint between the terminal pads and the electronic component is extremely high.

### CROSS REFERENCE TO RELATED APPLICATIONS

The present application claims priority from Japanese Patent Application No. 2010-249871, which was filed on Nov. 8, 2010, the disclosure of which is herein incorporated by reference in its entirety.

### BACKGROUND OF THE INVENTION

1. Field of the Invention

The present invention relates to an electronic-component-mounted wiring substrate which includes a laminated substrate, such as a coreless substrate comprised of conductor layers and resin insulation layers laminated alternately, and in which an electronic component, such as a chip capacitor, is mounted on terminal pads of the laminated substrate by means of a joining material including solder and an electrically insulating material, and to a method of manufacturing the same.

2. Description of Related Art

In a widely known conventional method of mounting electronic components such as chip capacitors (CPs) on a wiring substrate (e.g., a semiconductor package), terminals or bumps provided on the electronic components are joined, by means of solder, to terminal pads formed on the wiring substrate.

In a known method of mounting electronic components by means of such solder joining, there has been used a joining material prepared by mixing solder particles into a thermosetting resin. In this method, a joining material is supplied onto terminal pads of a wiring substrate in advance before electronic components are mounted thereon, and, after mounting of the electronic components on the wiring substrate, the wiring substrate is heated. Thus, solder particles melt and then solidify, whereby solder joint portions are formed. In addition, the thermosetting resin softens and then sets, whereby resin layers are formed. With this process, the terminals or bumps of the electronic components are electrically connected to the terminal pads of the wiring substrate by means of solder joining, and the thermosetting resin covers the solder joint portions to thereby reinforce them (see Patent Documents 1 and 2).

### RELATED ART DOCUMENTS

### Patent Documents

Patent Document 1 is Japanese Patent Application Laid-open (kokai) No. 2010-140924. Patent Document 2 is Japanese Patent Application Laid-open (kokai) No. 2010-161419.

### BRIEF SUMMARY OF THE INVENTION

However, in the case of the above-described conventional technique, since solder joined to terminal pads of a wiring substrate does not provide satisfactory joining reliability, the conventional technique has a problem in that electronic components cannot be joined to the terminal pads with satisfactory joining reliability. The joining reliability of solder and the reliability of joining of electronic components have not yet be studied sufficiently, in particular for the case where the terminal pads project from the surface of the wiring substrate.

Furthermore, in the case where the terminal pads project from the surface of the wiring substrate, a large clearance is formed between the wiring substrate and each electronic component. Thus, there arises a problem in that, when electronic components are mounted on the wiring substrate by means of melting the joining material, a clearance is likely to be formed between the electronic components and the wiring substrate.

That is, when the resin of the joining material fails to fill the clearance sufficiently, the wiring substrate may suffer insufficient strength and/or generation of warpage. In addition, in the case where the process of manufacturing the wiring substrate includes a step of re-heating the substrate after the electronic components are mounted thereon, the solder melts again and possibly enters such a clearance, with resultant formation of a short circuit.

The present invention has been conceived in view of the above problems, and an object of the invention is to provide an electronic-component-mounted wiring substrate which provides enhanced joining reliability when an electronic component is joined to terminal pads of the wiring substrate, which has sufficient strength, and which can prevent generation of warpage, as well as formation of a short circuit, which would otherwise occur as a result or re-melting of solder. Another object of the present invention is to provide a method of manufacturing the wiring substrate.

According to one aspect of the present invention, an electronic-component-mounted wiring substrate includes: a laminated substrate comprised of conductor layers and resin insulation layers laminated alternately and in which an electronic component is mounted on terminal pads on the laminated substrate by means of a joining material containing solder and an electrically insulating material. The terminal pads are provided on a surface of the laminated substrate such that they project therefrom. The terminal pads and terminals of the electronic component are joined together by the solder. The entire surface of each terminal pad is covered by the solder. The surface of the solder is covered by the electrically insulating material. The electrically insulating material comprises a resin and fills a clearance between the laminated substrate and the electronic component.

The entire surface of each terminal pad provided on the surface of the laminated substrate such that it projects therefrom (for example, side and upper surfaces of each laminated terminal pad project from the surface) is completely covered by solder, and this solder joins to the corresponding terminal of the electronic component. Therefore, the terminal pads and the solder (accordingly, the terminal pads and the electronic component) are joined reliably, and electrical continuity therebetween is secured sufficiently. That is, the present invention has a remarkable effect of realizing considerably high joint reliability for the joint between the solder and the terminal pads, and, therefore, for the joint between the terminal pads and the electronic component.

Notably, the phrase “considerably high joint reliability” means that the reliability of joint is sufficiently high so that, even in the case where an external force acts on the terminal pads or the electronic component or when the wiring substrate is used over a long period of time, the joint (between each terminal pads and solder) is unlikely to be broken, and reliable electrical continuity and joining performance can be secured for a long period of time.

Also, in the present invention, the surface of the solder is covered by the electrically insulating material, and the clearance between the laminated substrate and the electronic component is filled with the electrically insulating material; that is, the electrically insulating material completely fills the clearance between the laminated substrate and the electronic component. Therefore, the wiring substrate has increased strength, and warpage of the wiring substrate hardly occurs.

Moreover, the electrically insulating material is charged between the laminated substrate and the electronic component such that no clearance is formed therebetween even when the solder melts again as a result of heating after the electronic component is mounted on the substrate. Therefore, the solder does not flow into such a clearance, and a short circuit is hardly formed.

Notably, in some cases, fine voids are present between the laminated substrate and the electronic component. However, in the case where the electrically insulating material fills at least 90% the volume of the clearance between the laminated substrate and the electronic component, formation of a short circuit can be prevented.

A coreless substrate (with a substrate core removed) may be used as the laminated substrate.

Examples of the electronic component include a chip capacitor (CP), an inductor, a filter, and a resistor.

Examples of the material used to form the conductor layers and the terminal pads include copper, copper alloy, nickel, nickel alloy, tin, and tin alloy. The conductor layers and the terminal pads can be formed by a known process, such as a subtractive process, a semi-additive process, or a full-additive process. For example, etching copper foil, electroless copper plating, copper electroplating, or a like process is applied. Alternatively, the conductor layers and the terminal pads may be formed by a process of forming a thin film by spattering, CVD, or a like method, and etching the formed thin film. Alternatively, the conductor layers and the terminal pads may be formed by printing electrically conductive paste or the like.

The resin insulation layers can be selected properly in consideration of electrical insulation performance, heat resistance, moisture resistance, etc. Preferred examples of a polymeric material used to form the resin insulation layers include thermosetting resins, such as epoxy resin, phenol resin, urethane resin, silicone resin, and polyimide resin; and thermoplastic resins, such as polycarbonate resin, acrylic resin, polyacetal resin, and polypropylene resin. Additionally, there may be used a composite material consisting of any one of these resins, and glass fiber (glass woven fabric or glass nonwoven fabric) or organic fiber, such as polyamide fiber, or a resin-resin composite material in which a three-dimensional network fluorine-containing resin base material, such as continuously porous PTFE, is impregnated with a thermosetting resin, such as epoxy resin.

Examples of the solder contained in the joining material include Pb—Sn solder (e.g., 90 Pb-10 Sn, 95 Pb-5 Sn, 40 Pb-60 Sn), Sn—Bi solder, Sn—Sb solder, Sn—Ag solder, Sn—Ag—Cu solder, Au—Ge solder, and Au—Sn solder.

An example of the electrically insulating material contained in the joining material is thermosetting resin. An example of preferred thermosetting resins is epoxy resin. The usable type of the epoxy resin includes a bisphenol-A type, a bisphenol-F type, a multifunctional type, an alicyclic type, and a biphenyl type. Notably, not only epoxy resin but also acrylic resin, oxetane resin, polyimide resin, and isocyanate resin may be used as the thermosetting resin of the joining material.

In accord with one implementation, a plate-like stiffener (reinforcing plate) for increasing the strength of the laminated substrate is joined to the surface of the laminated substrate such that the stiffener surrounds the electronic component.

This configuration increases the strength of the wiring substrate, and is suitable particularly for the case where the wiring substrate is a coreless substrate.

Preferably, the stiffener is higher in stiffness than the materials that constitute the laminated substrate. The reason for making the stiffness of the stiffener higher than those of the materials of the laminated substrate is that, in the case where the stiffener itself has high stiffness, high stiffness is imparted to the wiring substrate by means of surface-joining the stiffener to the wiring substrate, whereby the wiring substrate becomes stronger against externally applied stresses. Furthermore, in the case where the stiffener has high stiffness, even when the thickness of the stiffener is reduced, a sufficiently high stiffness can be imparted to the wiring substrate. Thus, employment of the stiffener does not hinder thinning of the entire wiring substrate with the stiffener.

The material and dimensions of the stiffener are determined in consideration of the coefficient of thermal expansion of the laminated substrate and the required stiffness. Preferably, the stiffener is formed of a metallic material or a ceramic material which is high in stiffness. Alternatively, the stiffener may be formed of a resin material or a resin composite material which contains an inorganic material.

Examples of the metallic material used to form the stiffener include iron, gold, silver, copper, copper alloy, iron-nickel alloy, silicon, and gallium arsenide. Examples of the ceramic material used to form the stiffener include low-temperature fired materials (e.g., alumina, glass ceramic, and crystallized glass), aluminum nitride, silicon carbide, and silicon nitride. Examples of the resin material used to form the stiffener include epoxy resin, polybutene resin, polyamide resin, polybutylene terephthalate resin, polyphenylene sulfide resin, polyimide resin, bismaleimide-triazine resin, polycarbonate resin, polyphenylene ether resin, and acrylonitrile-butadien-styrene copolymer (ABS resin).

No limitation is particularly imposed on the method of joining the stiffener to the main surface of the laminated substrate, and a known method suitable for the nature of the material of the stiffener, the shape, etc. may be employed. For example, preferably, a joining surface of the stiffener is joined to the main surface of the laminated substrate via an adhesive. This method enables reliable and easy joining of the stiffener to the laminated substrate. Notably, examples of the adhesive include acrylic adhesive, epoxy adhesive, cyanoacrylate adhesive, and rubber adhesive.

In accord with another implementation, a thermosetting resin having a glass transition temperature equal to or lower than the melting point of the solder is used as the electrically insulating material.

This enables the thermosetting resin to be softened before the solder melts as a result of heating. Thus, it becomes possible to cause the solder in the softened thermosetting resin to melt and join to the terminal pads of the laminated substrate and the terminals of the electronic component.

A preferred example of the thermosetting resin is an epoxy resin. Other than that, acrylic resin, oxetane resin, polyimide resin, isocyanate resin, and the like can be employed.

The glass transition point may be 80° C. to 220° C., and the melting point of the solder may be 120° C. to 230° C.

According to another aspect of the present invention, a method of manufacturing an electronic-component-mounted wiring substrate in which an electronic component is mounted on terminal pads on a laminated substrate comprised of conductor layers and resin insulation layers laminated alternately, by making use of a joining material comprising solder and an electrically insulating material, the electrically insulating material comprising a resin, the method including: providing the terminal pads on a surface of the laminated substrate such that they project therefrom; disposing the joining material between the terminal pads and the terminals of the electronic component; and heating the joining material so as to melt the solder and soften the electrically insulating material; whereby the solder joins the terminal pads and the terminals of the electronic component together and covers the entire surface of each terminal pad, and the electrically insulating material covers the surface of the solder and fills a clearance between the laminated substrate and the electronic component.

In the present invention, the joining material in the form of, for example, paste is disposed between the terminal pads and the terminals of the electronic component, and is heated. Thus, the solder contained in the joining material melts (and then solidifies), whereby the solder joints the terminal pads and the terminals of the electronic component, and covers the entire surface of each terminal pad. Also, the electrically insulating material contained in the joining material softens (and then sets) as a result of the heating, whereby the electrically insulating material covers the surface of the solder.

Accordingly, in a wiring substrate manufactured by this method, the terminal pads and the electronic component are joined reliably, and electrical continuity is secured sufficiently. That is, an effect of realizing high joint reliability is attained. Furthermore, since the surface of the (solidified) solder is covered by the electrically insulating material, a high degree of insulation can be provided between the solder and the external environment.

Furthermore, in the present invention, through heating of the joining material, the electrically insulating material contained in the joining material is softened such that the electrically insulating material covers the surface of the solder and fills the clearance between the laminated substrate and the electronic component.

Accordingly, in a wiring substrate manufactured by this method, the electrically insulating material completely fills the space between the laminated substrate and the electronic component such that no clearance remains therebetween. Therefore, the wiring substrate has an increased strength, and warpage of the wiring substrate hardly occurs. Moreover, even when the solder melts again as a result of heating after the electronic component is mounted on the substrate, the solder does not flow into such a clearance. Therefore, formation of a short circuit hardly occurs.

The joining material may be paste prepared by mixing solder (solder particles, etc.) in a resin such as thermosetting resin. In addition to the resin and the solder, the joining material may contain other various components. For example, in the case where the resin is thermosetting resin, in addition to the thermosetting resin and the solder, the joining material may contain an agent for curing the thermosetting resin, an activator for imparting an activating action for removing oxide film from the solder, a thixotropic agent for adjusting the thixotropic degree of paste, and other additives. The incorporation amounts of these agents properly are adjusted in accordance with the solder content of the joining material, the particle size of the solder, and the degree of progress of oxidation of an object to be joined.

As described above, epoxy resin is a preferred example of thermosetting resin. The usable type of epoxy resin includes a bisphenol-A type, a bisphenol-F type, a multifunctional type, an alicyclic type, and a biphenyl type.

The curing agent may be of a type selected in accordance with a thermosetting resin to be used. In the case where the thermosetting resin to be used is epoxy resin, an imidazol, an anhydride, an amine, a hydrazide, and a micro-capsule-type curing agent are selectively used. The above-described activator may be one used for general cream solder, such as inorganic halide, amine, or organic acid. The above-mentioned thixotropic agent includes inorganic fine powder generally used for bonding agents for electronic materials.

Furthermore, a silane coupling agent, an organic solvent, a flexibility imparting material, a pigment, a catalyst, etc. are incorporated into the joining material as additives if necessary. The silane coupling agent is incorporated into the joining material so as to improve adhesiveness, and the organic solvent is used to adjust the viscosity of the joining material.

In accord with an implementation, the method further comprises cooling the joining material after heating such that the solder and the electrically insulating material become solid. The joining material is in a form of paste. The ratio of the solder is 50% by weight to 95% by weight, preferably, 80% by weight to 90% by weight, and the ratio of the electrically insulating resin material is 5% by weight to 50% by weight, preferably, 10% by weight to 20% by weight.

By virtue of this configuration, the entire surface of each terminal pad can be readily covered with the solder, and the terminal pads and the electronic component can be joined firmly. In addition, the surface of the solder can be readily covered with the electrically insulating material, and the clearance between the laminated substrate and the electronic component can be filled with the electrically insulating material.

In accord with another implementation, the joining material has a viscosity which falls within a range of 50 Pa·s to 500 Pa·s, inclusive, at 25° C., preferably, within a range of 200 Pa·s to 250 Pa·s, inclusive, at 25° C.

The viscosity within such a range enables the joining material to have appropriate flowability and appropriate joining performance. Therefore, when an electronic component is placed on the joining material disposed on the terminal pads, the joining material properly spreads to an area around the electronic component, and at the time of subsequent heating, the melted solder and the softened electrically insulating material flow properly.

Other features and advantages will be set forth in, or apparent from, the detailed description of exemplary embodiments of the invention found below.

### BRIEF DESCRIPTION OF THE DRAWINGS

Illustrative aspects of the invention will be described in detail with reference to the following figures wherein:

FIG. 1 is a sectional view (cross section taken along line A-A of FIG. 2) of a wiring substrate;

FIG. 2 is a plan view showing a first main surface side of the wiring substrate;

FIG. 3 is a plan view showing a first main surface side of a laminated substrate;

FIG. 4 is a plan view showing a stiffener;

FIG. 5 is a bottom view showing a second main surface side of the laminated substrate;

FIG. 6 is a sectional view showing, on an enlarged scale, a portion of a vertical cross section (cross section orthogonal to the main surface) of the laminated substrate;

FIG. 7 is an explanatory view showing a vertical cross section of a chip capacitor and its surrounding;

FIGS. 8A to 8E are vertical cross sections of relevant members showing steps of a method of manufacturing the wiring substrate;

FIGS. 9A to 9C are vertical cross sections of relevant members showing steps of the method of manufacturing the wiring substrate;

FIGS. 10A and 10B are vertical cross sections of relevant members showing steps of the method of manufacturing the wiring substrate;

FIGS. 11A and 11B are vertical cross sections of relevant members showing steps of the method of manufacturing the wiring substrate;

FIGS. 12A to 12E are explanatory views showing steps of joining a chip capacitor; and

FIG. 13 is an explanatory view showing a method of joining a stiffener.

### DETAILED DESCRIPTION OF EXEMPLARY EMBODIMENTS OF THE INVENTION

An embodiment of the present invention will next be described in detail with reference to the drawings.

Here, there will be described an electronic-component-mounted wiring substrate in which chip capacitors are mounted on one main surface of a coreless substrate, and a stiffener is joined to the main surface.

a) First, the structure of an electronic-component-mounted wiring substrate (hereinafter simply referred to as the “wiring substrate”) of the present embodiment will be described with reference to FIGS. 1 to 7.

As shown in FIG. 1, the wiring substrate 1 of the present embodiment is a semiconductor package on which an IC chip 3 is to be mounted. This wiring substrate 1 is mainly composed of a coreless substrate (laminated substrate) 5 formed without use of a substrate core. A large number of chip capacitors (CPs) 9 are mounted on one main surface (a first main surface located on the upper side in FIG. 1) of the laminated substrate 5; i.e., on the side where an IC chip 3 is to be mounted, such that the chip capacitors (CPs) 9 surround a mounting region 7 in which the IC chip 3 is to be mounted. In addition, a reinforcing member (stiffener) 11 is joined to the main surface of the laminated substrate 5.

The structure of the wiring substrate 1 will now be described in detail.

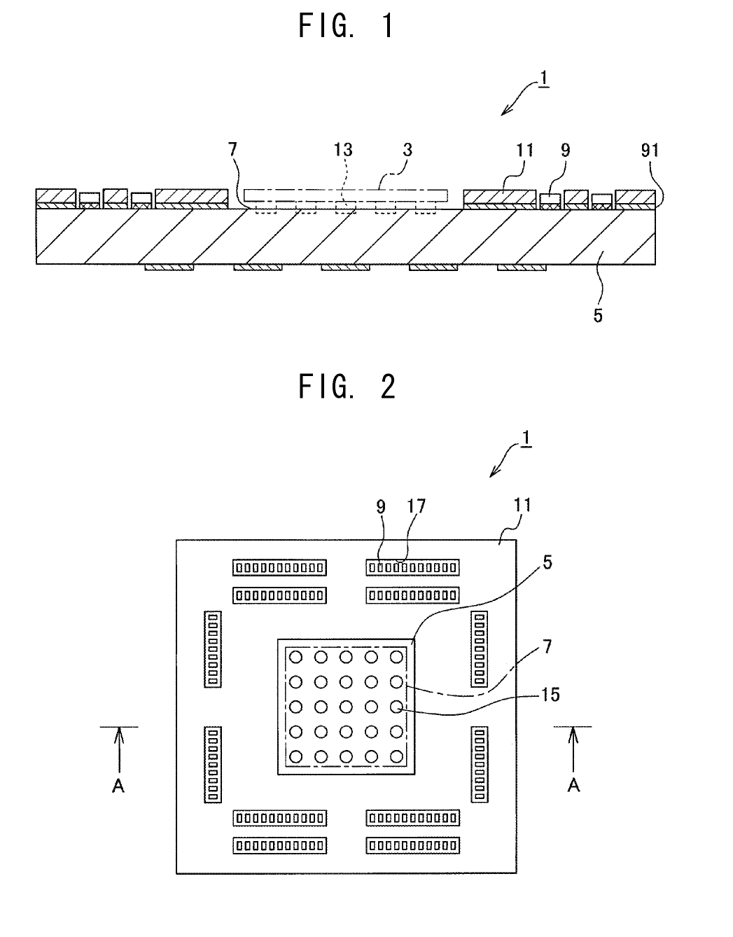

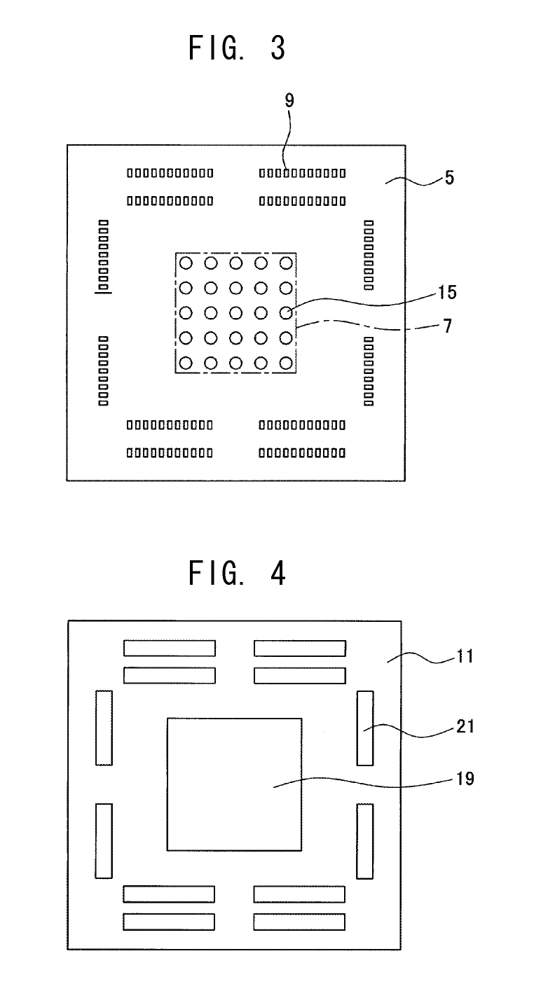

As shown in FIGS. 2 and 3, the mounting region 7, which has an approximately square shape, is provided on the first main surface of the laminated substrate 5 at the center thereof. A plurality of terminal pads 15 for an IC chip (hereinafter referred to as the IC chip terminal pads 15) are formed in an array in the mounting region 7, and solder bumps 13 (see FIG. 1) for joining the IC chip 3 to the laminated substrate 5 are formed on the terminal pads 15.

Also, a large number of chip capacitors 9 are mounted on the first main surface to be located around (along four sides) of the mounting region 7.

Furthermore, a square stiffener 11 formed of, for example, copper is joined to the first main surface such that the stiffener 11 covers the first main surface, excluding the mounting region 7 for the IC chip 3 and rectangular mounting regions 17 for the chip capacitors 9. That is, as shown in FIG. 4, a square first opening 19 corresponding to the mounting region 7 for the IC chip 3 is provided at the center of the stiffener 11, and a plurality of rectangular second openings 21 corresponding to the mounting regions 17 for the chip capacitors 9 are provided around the first opening 19.

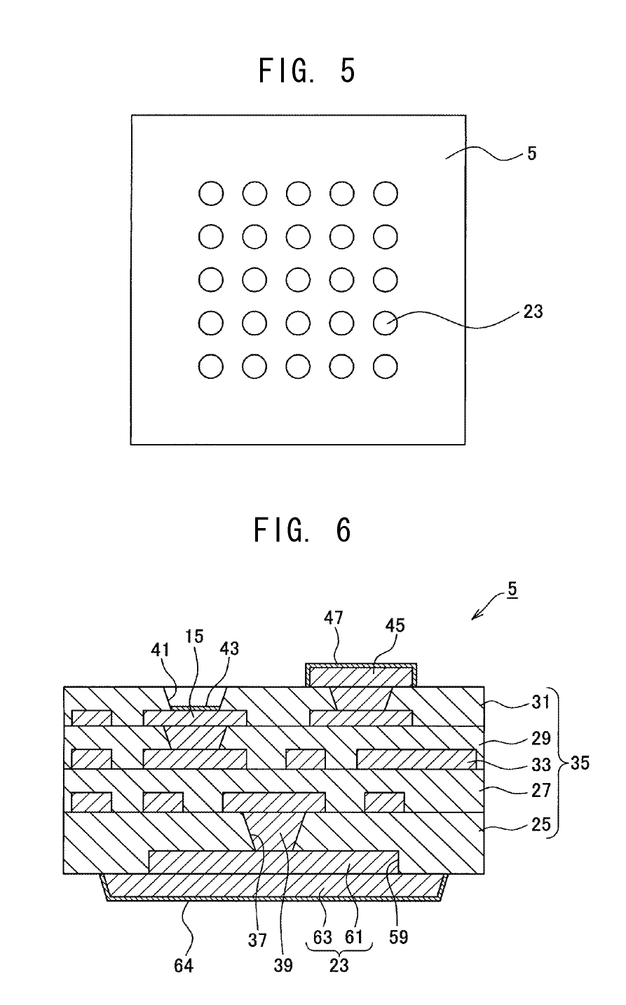

Meanwhile, as shown in FIG. 5, a plurality of terminal pads 23 for a motherboard (hereinafter referred to as the “motherboard terminal pads 23”) are formed on the back side (second main surface side) of the laminated substrate 5 so as to form an LGA (land grid array) to which an unillustrated motherboard is to be joined.

As shown in FIG. 6, which shows a portion of the wiring substrate on an enlarged scale, the laminated substrate 5 has a wiring laminate portion 35 in which a plurality of (for example, four) resin insulation layers 25, 27, 29, and 31 made primarily of the same resin insulation material (electrically insulating material), and conductor layers 33 made of copper are laminated alternately.

The resin insulation layers 25 to 31 are formed of a build-up material made primarily of a hardened resin insulation material that is not photocurable; specifically, a hardened thermosetting epoxy resin.

Via holes 37 and via conductors 39 are provided in the resin insulation layers 25 to 31. The via conductors 39 are shaped such that their diameters increase toward the first main surface side. The via conductors 39 electrically interconnect the conductor layers 33, the IC chip terminal pads 15, and the motherboard terminal pads 23.

On the side toward the first main surface of the wiring laminate portion 35, a plurality of front surface openings 41 are formed in the outermost resin insulation layer 31. The IC chip terminal pads 15 are formed in the front surface openings 41 such that the IC chip terminal pads 15 become lower than (i.e., is recessed from) the outside surface of the resin insulation layer 31. Notably, each of the IC chip terminal pads 15 has a structure in which only the upper surface of a copper layer which mainly forms the pad is covered with a plating layer 43 of a material other than copper (specifically, a nickel-gold plating layer).

Also, on the side toward the first main surface of the laminated substrate 5, there are formed the capacitor terminal pads 45, to which the chip capacitors 9 are joined. The capacitor terminal pads 45 are mainly formed of a copper layer and each assumes a convex shape (plate-like shape) such that the upper surfaces of the capacitor terminal pads 45 become higher than (i.e., protrudes from) the surface of the resin insulation layer 31.

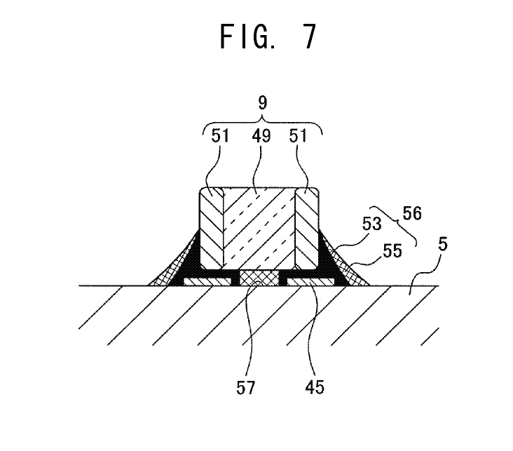

Each of the capacitor terminal pads 45 has a structure in which the upper and side surfaces of a copper layer which mainly forms the pad are covered with a plating layer 47 of a material other than copper (specifically, a nickel-gold plating layer). As shown in FIG. 7 on an enlarged scale, the chip capacitors 9 are connected to the capacitor terminal pads 45.

Each chip capacitor 9 includes a central portion 49, and capacitor terminals 51 provided at opposite ends of the central portion 49. The capacitor terminals 51 are joined to the corresponding capacitor terminal pads 45 via a solder joint portion 53 formed of solder.

Specifically, the side and upper surfaces (that is, the entire surface) of each capacitor terminal pad 45 are covered by solder (for example, Sn—Bi solder), and the greater portions of the bottom and side surfaces of the capacitor terminals 51 are also covered by the solder. Thus, the capacitor terminal pads 45 and the chip capacitor 9 are electrically connected together, and are firmly joined together. Notably, the solder joint portion 53 assumes a fillet shape such that it extends from the side surfaces of the capacitor terminals 51 to the surface of the laminated substrate 5; that is, the cross sectional area increases toward the laminated substrate 5.

The entire surface of the solder joint portion 53 is covered by an electrically insulating material 55 (i.e., thermosetting resin such as epoxy resin). Also, the thermosetting resin joins to a surface region of the laminated substrate 5 around the solder joint portion 53. Further, the thermosetting resin completely fills a clearance 57 between the bottom surface of the chip capacitor 9 and the upper surface of the laminated substrate 5. Thus, the laminated substrate 5 and the chip capacitor 9 are firmly joined together, and excellent insulation is provided between the solder joint portion 53 and the surrounding atmosphere.

That is, by virtue of the configurations of the solder joint portion 53 and the electrically insulating material 55 (the configuration of the solidified joining material 56), electrical continuity between the capacitor terminal pads 45 and the chip capacitor 9 is secured, and the laminated substrate 5 and the chip capacitor 9 are strongly joined together.

Notably, the thermosetting resin used in the present embodiment has a glass transition temperature equal to or lower than the melting point of the solder. For example, in the present embodiment, a thermosetting resin whose glass transition temperature is 80° C. to 220° C. (e.g., 95° C.) is used; and Sn—Bi solder whose melting point is 120° C. to 230° C. (e.g., 139° C.) is used.

Referring back to FIG. 6, on the side toward the lower surface (second main surface) of the wiring laminate portion 35, a plurality of back surface openings 59 are formed in the outermost resin insulation layer 25, and the motherboard terminal pads 23 are disposed at positions corresponding to the back surface openings 59. Specifically, each of the motherboard terminal pads 23 has a double layer configuration; i.e., is composed of a lower metal conductor portion 61 located in the corresponding back surface opening 59, and an upper metal conductor portion 63 covering the lower metal conductor portion 61 and an area around the lower metal conductor portion 61. Notably, each of the motherboard terminal pad 23 has a structure in which the upper and side surfaces of a copper layer which mainly forms the pad are covered with a plating layer 64 of a material other than copper (specifically, a nickel-gold plating layer).

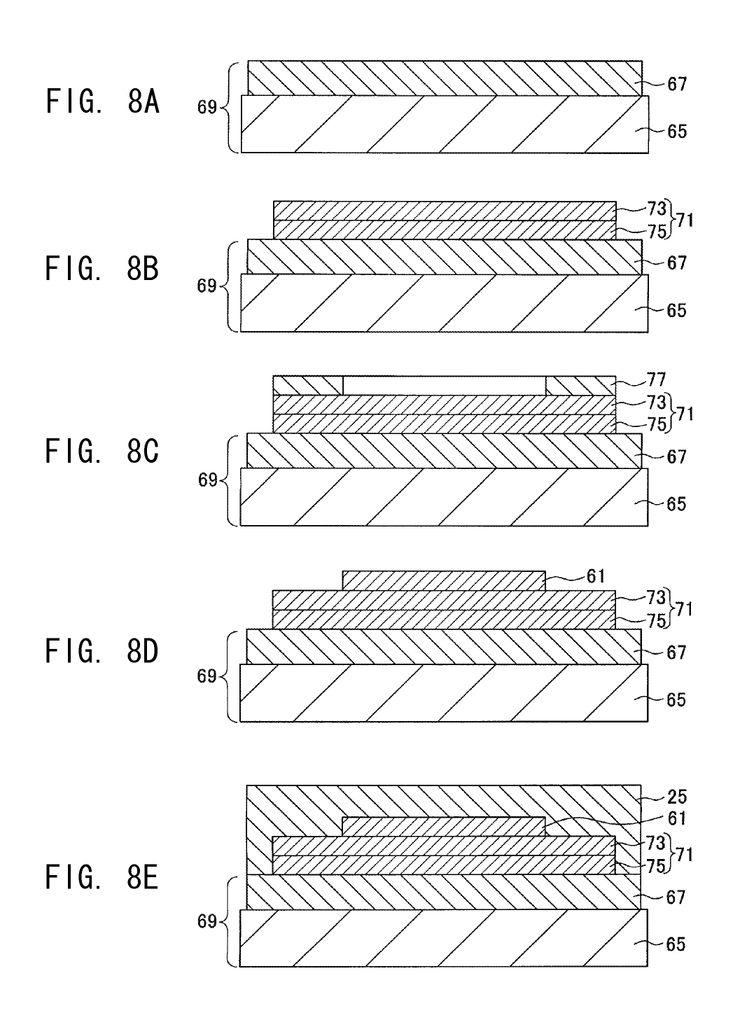

b) Next, a method of manufacturing the wiring substrate 1 of the present embodiment will be described with reference to FIGS. 8A to 13.

Laminated Substrate Manufacturing Step

First, a support substrate (a glass epoxy substrate or the like) having sufficient strength is prepared. On the support substrate, the resin insulation layers 25 to 31 and the conductor layers 33 are alternately built up, thereby forming the wiring laminate portion 35.

Specifically, as shown in FIG. 8A, a sheet-like electrically insulative resin base material made of epoxy resin and serving as a ground resin insulation layer 67 is attached onto a support substrate 65, thereby yielding a base material 69 consisting of the support substrate 65 and the ground resin insulation layer 67.

Next, as shown in FIG. 8B, a metal laminate sheet 71 is disposed on the upper surface of the base material 69. The metal laminate sheet 71 is configured such that two copper foils 73 and 75 are separably adhered to each other.

Next, as shown in FIG. 8C, in order to form the lower metal conductor portion 61, a plating resist layer 77 having a shape corresponding to that of the lower metal conductor portion 61 is formed on the upper surface of the metal laminate sheet 71.

Specifically, a dry film for formation of the plating resist layer 77 is laminated on the upper surface of the metal laminate sheet 71. The dry film is exposed to light and undergoes development, whereby the plating resist layer 77 is formed.

Next, as shown in FIG. 8D, copper electroplating is selectively performed with the plating resist layer 77 formed, whereby the lower metal conductor portion 61 is formed on the metal laminate sheet 71. After that, the plating resist layer 77 is peeled off.

Next, as shown in FIG. 8E, a sheet-like resin insulation layer 25 is disposed so as to cover the metal laminate sheet 71 and the lower metal conductor portion 61 formed thereon, such that the resin insulation layer 25 is in close contact with the lower metal conductor portion 61 and the metal laminate sheet 71.

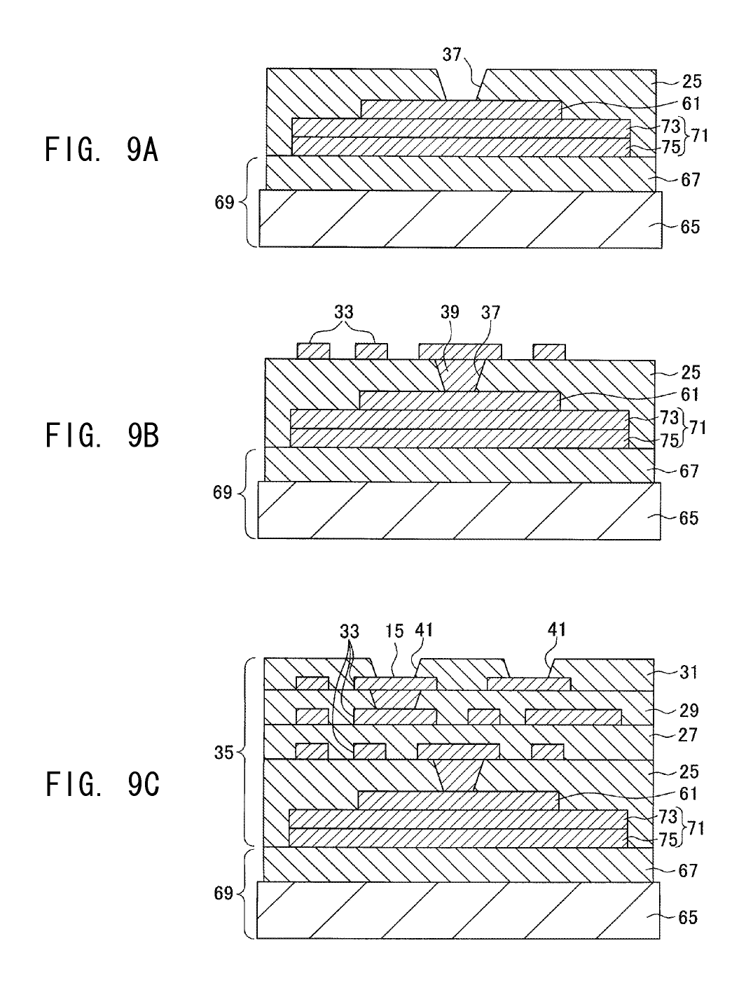

Next, as shown in FIG. 9A, the via holes 37 are formed in the resin insulation layer 25 at predetermined positions (above the lower metal conductor portions 61) by means of performing laser beam machining by use of, for example, an excimer laser, a UV laser, or a CO₂ laser. Next, smears are removed from the via holes 37 by use of etchant, such as a potassium permanganate solution, or O₂ plasma.

Next, as shown in FIG. 9B, electroless copper plating and copper electroplating are performed by a known process, thereby forming the via conductors 39 in the via holes 37. Further, etching is performed by a known process (e.g., semi-additive process), thereby forming the conductor layer 33 in a predetermined pattern on the resin insulation layer 25.

Next, as shown in FIG. 9C, other resin insulation layers 27 to 31 and the corresponding conductor layers 33 are successively formed by processes similar to those used to form the resin insulation layer 25 and the associated conductor layer 33. The plurality of front surface openings 41 are then formed in the outermost resin insulation layer 31 by means of laser machining. Subsequently, smears are removed from the front surface openings 41 by use of a potassium permanganate solution or O₂ plasma.

Next, electroless copper plating is performed on the upper surface of the resin insulation layer 31 to thereby form a full surface plating layer (not shown) which fills the front surface openings 41 of the resin insulation layer 31 and covers the resin insulation layers 31. Subsequently, a plating resist layer (not shown) which is similar to the above-described plating resist layer and has openings at positions corresponding to the capacitor terminal pads 45 is formed on the upper surface of the wiring laminate portion 35.

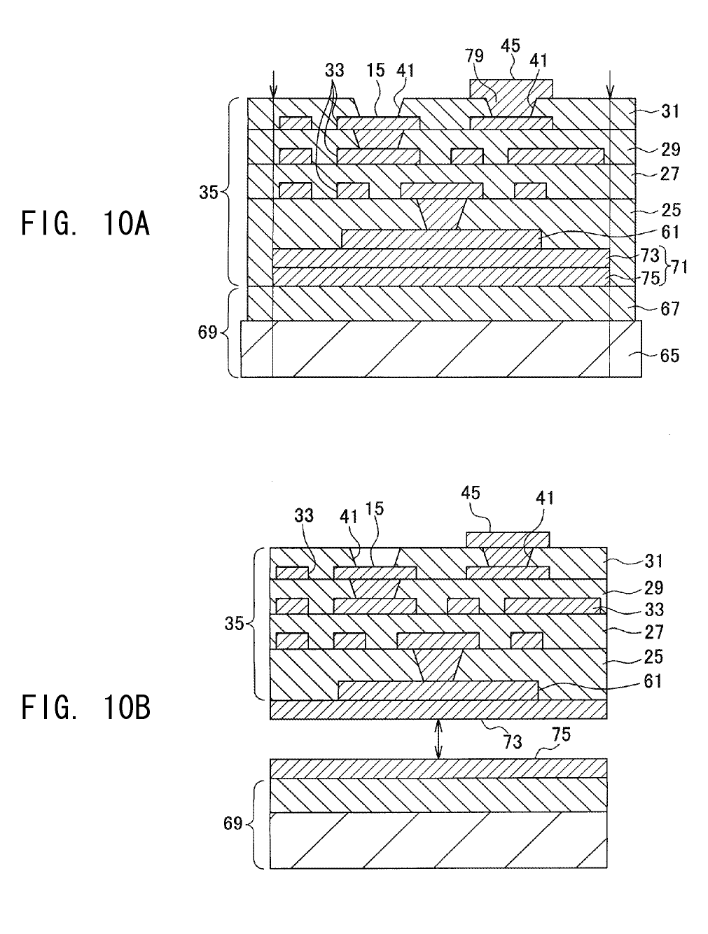

Subsequently, pattern plating is selectively performed on the substrate surface with plating resist formed thereon, whereby, as shown in FIG. 10A, via conductors 79 are formed in some of the plurality of front surface openings 41, and the capacitor terminal pads 45 are formed on the via conductors 79. After that, pattering is performed by a semi-additive process, whereby the above-described full surface plating layer is removed in such a manner that the via conductors 79 and the capacitor terminal pads 45 remain.

Next, the wiring laminate portion 35 is cut by a dicing apparatus (not shown) so as to remove a surrounding portion around the wiring laminate portion 35.

Next, as shown in FIG. 10B, through separation at the interface between the two foils 73 and 75 of the metal laminate sheet 71, the base material 69 is removed form the wiring laminate portion 35, whereby the copper foil 73 is exposed.

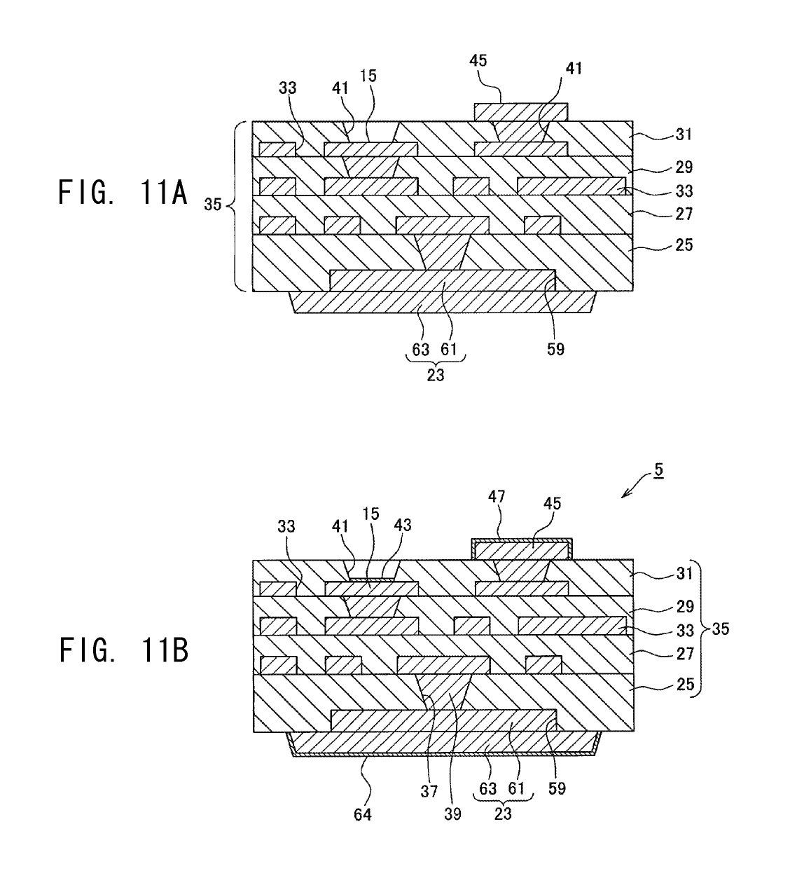

Next, as shown in FIG. 11A, on the lower surface side (the second main surface side) of the wiring laminate portion 35, the copper foil 73 is partially removed, through etching, such that the lower metal conductor portions 61 remain, whereby the upper metal conductor portions 63 are formed.

Next, as shown in FIG. 11B, electroless copper plating and electroless gold plating are successively performed on the surfaces of the IC chip terminal pads 15, the capacitor terminal pads 45, and the motherboard terminal pads 23 so as to form the nickel-gold plating layers 43, 47, and 64, whereby the laminated substrate 5 is completed.

Chip Capacitor Joining Step

Herein, there will be described a method of joining the chip capacitors 9 to the capacitor terminal pads 45 on the laminated substrate 5.

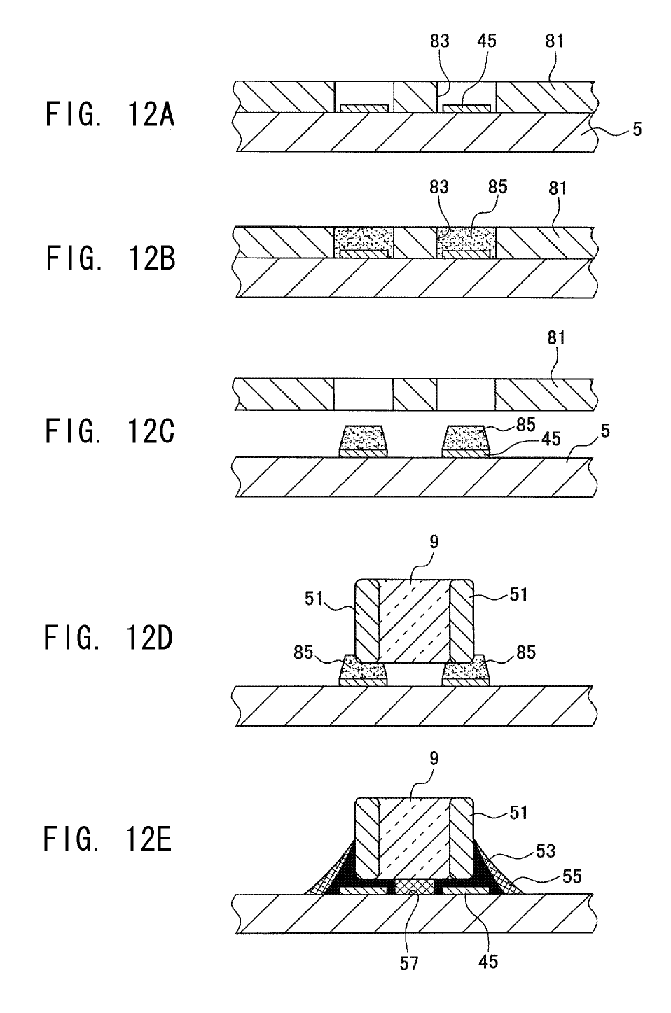

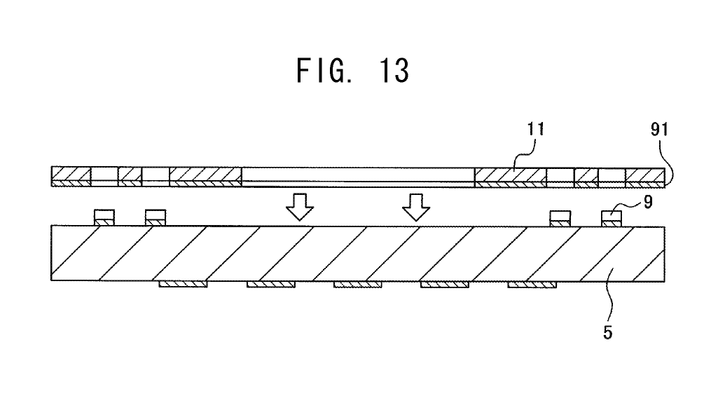

First, as shown in FIG. 12A, which shows a main portion on an enlarged scale, a mask 81 for solder printing is disposed on the laminated substrate 5 manufactured by the above-described manufacturing method. Openings 83 having a shape similar to the planar shape of the capacitor terminal pads 45 are formed in the mask 81 for solder printing at positions corresponding to the capacitor terminal pads 45.

Next, as shown in FIG. 12B, a well-known printing operation is performed by use of the mask 81 for solder printing and a joining material in the form of paste (joining paste) 85, which is a printing material, whereby the joining paste 85 is charged into the openings 83 of the mask 81 for solder printing.

Here, the joining paste 85 will be described.

The joining paste 85 used in the present embodiment contains not only solder and thermosetting resin but also various components (e.g., organic solvent and additives) for obtaining the joining material in the form of paste. The joining paste 85 contains Sn—Bi solder (86% by weight), epoxy resin, which is a thermosetting resin, (11% by weight), and other components (3% by weight).

The ratios in weight of the solder and the thermosetting resin to the solid components (that is, the solder and the thermosetting resin) remaining after joining are determined such that the ratio of the solder falls within a range of 50% by weight to 95% by weight; for example, the ratio of the solder is 96% by weight; and the ratio of the thermosetting resin falls within a range of 5% by weight to 50% by weight, for example, the ratio of the thermosetting resin is 14% by weight. The viscosity of the joining paste 85 falls within a range of 50 Pa·s to 500 Pa·s, inclusive, at 25° C.; for example, the viscosity of the joining paste 85 is 250 Pa·s at 25° C.

Next, as shown in FIG. 12C, the mask 81 for solder printing is peeled off the laminated substrate 5. As a result, a layer of the joining paste 85 is formed on each of the capacitor terminal pads 45.

Next, as shown in FIG. 12D, each chip capacitor 9 is placed on two layers of the joining paste 85 on two of the capacitor terminal pads 45, and is pressed against the layers. Specifically, one (left-hand-side in FIG. 12D) capacitor terminal 51 of the chip capacitor 9 is placed on one layer of the joining paste 85, and the other (right-hand-side in FIG. 12D) capacitor terminal 51 of the chip capacitor 9 is placed on the other layer of the joining paste 85.

Next, as shown in FIG. 12E, heating is performed in a state in which the chip capacitor 9 is placed on the layers of the joining paste 85, whereby the chip capacitor 9 is joined to the corresponding capacitor terminal pads 45.

Specifically, there is applied a heating profile set on the basis of, for example, a heating temperature within a range of 140° C. to 230° C. and a heating time within a range of 5 sec to 300 sec. In the present embodiment, the heating temperature is set to 180° C., and the heating time is set to 180 sec. Notably, the heating temperature is set to be higher than the above-described melting temperature of the solder and the above-described glass transition temperature of the thermosetting resin.

Accordingly, in the present embodiment, the epoxy resin contained in the joining paste 85 softens when it is heated to a temperature (e.g., 120° C.) equal to or higher than the glass transition temperature of the epoxy resin. The softened epoxy resin enters the clearance 57 between the bottom surface of each chip capacitor 9 and the laminated substrate 5 such that the epoxy resin fills at least 90% the volume of the clearance 57.

After that, the joining paste 85 is further heated to a temperature (e.g., 140° C.) at which the solder melts. As a result, within the softened epoxy resin, particles of the solder melt and unify, whereby the solder covers and comes into contact with the entire surface of the capacitor terminal pad 45, and also covers and comes into contact with the entire bottom surfaces of the capacitor terminals 51 and at least half of the side surfaces of the capacitor terminals (notably, after cooling, the solder joins to these surfaces with which the solder is in contact). Simultaneously, the epoxy resin covers the entire outer circumference of a portion which will become the solder joint portion 53 (after cooling). When the temperature increases further, the epoxy resin sets in this state.

After that, the temperature is lowered to room temperature. As a result, as shown in FIG. 12E, there can be obtained a joint structure for each chip capacitor 9 in which the circumference of the solder joint portion 53 is covered by the electrically insulating material 55.

Stiffener Joining Step

Here, there will be described a method of joining the stiffener 11 to the first main surface of the laminated substrate 5.

A metal plate formed of, for example, copper and having a thickness of 1 mm is machined, through punching or the like, into a shape shown in the above-described FIG. 4, whereby the stiffener 11 is fabricated.

Subsequently, as shown in FIG. 13, the stiffener 11 is joined to the first main surface of the laminated substrate 5. Specifically, an adhesive formed of, for example, acrylic resin, is applied to the back side of the stiffener 11 (the side to be joined to the laminated substrate 5). The stiffener 11 with the adhesive applied thereto is pressed against and joined to the first main surface of the laminated substrate 5.

As a result, there can be obtained the wiring substrate 1, in which, as shown in the above-described FIG. 1, the chip capacitors 9 are joined to the first main surface of the laminated substrate 5, and the stiffener 11 is joined to the first main surface by the adhesive layer 91, while avoiding the chip capacitors 9.

c) As described above, in the present embodiment, the entire surface of each capacitor terminal pad 45 provided on the laminated substrate 5 to project therefrom is completely covered by solder, which joins to the capacitor terminals 51. Therefore, the capacitor terminal pads 45 and the solder (accordingly, the capacitor terminal pads 45 and the chip capacitor 9) are joined together reliably, and sufficient electrical continuity is secured therebetween. That is, the present embodiment provides a remarkable effect of realizing considerably high joint reliability for the joint between the solder and the capacitor terminal pads 45, and, therefore, for the joint between the capacitor terminal pads 45 and the chip capacitors 9.

Also, in the present embodiment, the surface of the solder is covered by epoxy resin (having electrically insulating performance), and the clearance 57 between the laminated substrate 5 and each chip capacitor 9 is filled with the epoxy resin. That is, since the epoxy resin completely fills the clearance between the laminated substrate 5 and each chip capacitor 9, the wiring substrate 1 has increased strength, and warpage of the wiring substrate 1 hardly occurs.

Moreover, the epoxy resin is charged between the laminated substrate 5 and each chip capacitor 9 such that no clearance is formed therebetween even when the solder melts again as a result of heating after the chip capacitor 9 is mounted on the substrate. Therefore, the solder does not flow into such a clearance, and a short circuit is avoided.

In addition, in the present embodiment, the plate-like stiffener 11 is joined to the front surface of the laminated substrate 5 to surround the chip capacitors 9. This configuration increases the strength of the wiring substrate 1, and is suitable particularly for the case where the wiring substrate 1 is a coreless substrate.

Moreover, in the present embodiment, the glass transition temperature of the epoxy resin used as a component of the joining paste 85 is equal to or lower than the melting point of the solder. This enables the epoxy resin to soften before the solder melts through heating. Thus, it becomes possible to cause the solder in the softened epoxy resin to melt and join to the capacitor terminal pads 45 of the laminated substrate 5 and the capacitor terminals 51.

In the case where the wiring substrate 1 having the above-described configuration is manufactured, the joining paste 85 is disposed between the capacitor terminal pads 45 and the capacitor terminals 51, and is heated. Thus, the solder contained in the joining past 85 melts (and then solidifies), whereby the solder joins the capacitor terminal pads 45 and the capacitor terminals 51 together, and covers the entire surface of each capacitor terminal pad 45. Also, the epoxy resin contained in the joining paste 85 softens as a result of heating (and then sets), whereby the epoxy resin covers the surface of the solder.

Moreover, in the present embodiment, the ratio of the epoxy resin to the components of the joining paste 85 is 5% by weight to 50% by weight. Therefore, the entire surface of each capacitor terminal pad 45 can be readily covered with the solder, and the capacitor terminal pads 45 and the corresponding chip capacitor 9 can be joined firmly. In addition, the surface of the solder can be readily covered with the epoxy resin, and the clearance 57 between the laminated substrate 5 and each chip capacitor 9 can be filled with the epoxy resin.

In addition, the joining past 85 has a viscosity which falls within a range of 50 Pa·s to 500 Pa·s, inclusive, at 25° C. Therefore, the joining paste 85 has appropriate flowability and appropriate joining performance. Therefore, when each chip capacitor 9 is placed on the joining paste 85 disposed on the corresponding capacitor terminal pads 45, the joining paste 85 properly spreads to an area around the chip capacitor 9, and, at the time of subsequent heating, the melted solder and the softened epoxy resin flow properly.

Notably, the present invention is not limited to the above-described embodiment, and various forms may be employed without departing from the technical scope of the present invention.

### DESCRIPTION OF REFERENCE NUMERALS

1: electronic-component-mounted wiring substrate
3: IC chip
5: laminated substrate
11: stiffener
25, 27, 29, 31: resin insulation layer
33: conductor
45: capacitor terminal pad
53: solder joint portion
55: electrically insulating material
56: joining material
57: clearance
85: joining paste

What is claimed is:

1. An electronic-component-mounted wiring substrate comprising:
a laminated substrate comprised of conductor layers and resin insulation layers laminated alternately and in which an electronic component is mounted on terminal pads on the laminated substrate by means of a joining material containing solder and an electrically insulating material, wherein:
the terminal pads are provided on a surface of the laminated substrate such that they project therefrom;
the terminal pads and terminals of the electronic component are joined together by the solder;
the entire surface of each terminal pad is covered by the solder;
the surface of the solder is covered by the electrically insulating material; and
the electrically insulating material comprises a resin and fills a clearance between the laminated substrate and the electronic component.

2. The electronic-component-mounted wiring substrate according to claim 1, wherein a plate-like stiffener for increasing strength of the laminated substrate is joined to the surface of the laminated substrate such that the stiffener surrounds the electronic component.

3. The electronic-component-mounted wiring substrate according to claim 1, wherein the electrically insulating material is formed of a thermosetting resin and has a glass transition temperature equal to or lower than a melting point of the solder.

4. A method of manufacturing an electronic-component-mounted wiring substrate in which an electronic component is mounted on terminal pads on a laminated substrate comprised of conductor layers and resin insulation layers laminated alternately, by making use of a joining material comprising solder and an electrically insulating material, the electrically insulating material comprising a resin, the method comprising:
providing the terminal pads on a surface of the laminated substrate such that they project therefrom;
disposing the joining material between the terminal pads and terminals of the electronic component; and
heating the joining material so as to melt the solder and soften the electrically insulating material;
whereby the solder joins the terminal pads and the terminals of the electronic component together and covers the entire surface of each terminal pad, and the electrically insulating material covers the surface of the solder and fills a clearance between the laminated substrate and the electronic component.

5. The method of manufacturing an electronic-component-mounted wiring substrate according to claim 4, further comprising cooling the joining material after the heating such that the solder and the electrically insulating material become solid, wherein the joining material is in a form of paste, and wherein a ratio of the solder is 50% by weight to 95% by weight, and a ratio of the electrically insulating material is 5% by weight to 50% by weight.

6. The method of manufacturing an electronic-component-mounted wiring substrate according to claim 4, wherein the joining material has a viscosity which falls within a range of 50 Pa·s to 500 Pa·s, inclusive, at 25° C.
